(19) United States
(12) Patent Application Publication
(10) Pub. No.: US 2018/0166555 A1
(43) Pub. Date: Jun. 14, 2018

(54) Silicon Carbide Vertical MOSFET with Polycrystalline Silicon Channel Layer

(71) Applicant: Infineon Technologies AG, Neubiberg (DE)

(72) Inventors: Anton Mauder, Kolbermoor (DE); Roland Rupp, Lauf (DE); Hans-Joachim Schulze, Taufkirchen (DE)

(21) Appl. No.: 15/880,716

(22) Filed: Jan. 26, 2018

Related U.S. Application Data
(62) Division of application No. 13/621,834, filed on Sep. 17, 2012.

(30) Foreign Application Priority Data
Sep. 15, 2011 (DE) 102011053641.8

(51) Int. Cl. H01L 29/66; H01L 29/165; H01L 29/78; H01L 29/06; H01L 29/40; H01L 29/16; H01L 29/10; H01L 29/08; H01L 29/417; H01L 29/423

(52) U.S. Cl. CPC H01L 29/66068; H01L 29/165; H01L 29/7813; H01L 29/7802; H01L 29/0696; H01L 29/402; H01L 29/408; H01L 29/1095; H01L 29/0878; H01L 29/417; H01L 29/41766; H01L 29/42376; H01L 29/1608

(57) ABSTRACT

A semiconductor device may include a semiconductor body of silicon carbide (SiC) and a field effect transistor. The field effect transistor has the semiconductor body that includes a drift region. A polycrystalline silicon layer is formed over or on the semiconductor body, wherein the polycrystalline silicon layer has an average particle size in the range of 10 nm to 5 μm, and includes a source region and a body region. Furthermore, the field effect transistor includes a layer adjacent to the body region gate structure.

### RELATED APPLICATIONS

This Application claims priority benefit of German Patent Application 102011053641.8, which was filed on Sep. 15, 2011. The entire contents of the German Patent Application are incorported herein by reference.

### BACKGROUND

The application relates to a semiconductor device and a method for manufacturing a semiconductor device.

Silicon carbide (SiC) is a semiconductor material having desirable properties for many applications. The desirable properties of SiC include a high maximum electron velocity, which allows operation of SiC components at high frequencies, a high thermal conductivity, which enables SiC components to dissipate excess heat, and a high breakdown electric field strength, which enables SiC components to be operated at high voltage levels.

SiC field effect transistor devices which have a small turn-on resistance are desirable. Furthermore, it is also desirable to provide semiconductor arrangements that are not significant in size.

### SUMMARY

The detailed description is described with reference to the accompanying figures. In the figures, the left-most digit(s) of a reference number identifies the figure in which the reference number first appears. The use of the same reference number in different instances in the description and the figures may indicate similar or identical items.

Embodiments provide a SiC semiconductor device having increased mobility in the inversion channel, in spite of a reduction of the on-resistance. Furthermore, embodiments provide a SiC semiconductor device having good resistance in the inversion channel. Further embodiments are dedicated to a corresponding manufacturing method of a semiconductor device.

An embodiment relates to a semiconductor device comprising a semiconductor body of silicon carbide (SiC) and a field effect transistor. The field effect transistor has the semiconductor body that includes a drift region. A polycrystalline silicon layer is formed over or on the semiconductor body, wherein the polycrystalline silicon layer has an average particle size in the range of 10 nm to 5 μm, and includes a source region and a body region. Furthermore, the field effect transistor includes a gate structure layer adjacent to the body region.

A method for producing a semiconductor device according to an embodiment comprises forming a polycrystalline silicon layer over or on a semiconductor body made of SiC, wherein the polycrystalline silicon layer has an average particle size in the range of 10 nm to 5 μm. According to this method, a body region and a source region may be formed within the polycrystalline silicon layer, and a body region may be formed next to the gate structure.

### BRIEF DESCRIPTION OF THE DRAWINGS

The detailed description is described with reference to the accompanying figures. In the figures, the left-most digit(s) of a reference number identifies the figure in which the reference number first appears. The use of the same reference number in different instances in the description and the figures may indicate similar or identical items.

FIG. 1 illustrates a cross-sectional view of a semiconductor device with a semiconductor body made of SiC, and a field effect transistor having a polycrystalline silicon layer in which a channel is provided.

FIGS. 2A-2C illustrate diagrammatic plan views of alternative embodiments of the semiconductor device according to FIG. 1.

FIGS. 3A and 3B illustrate cross-sectional views of field effect transistors having a polycrystalline silicon layer with a vertical channel, and a semiconductor body made of SiC.

FIGS. 4A-4C illustrate cross-sectional views of a field effect transistor device as an alternative to the embodiments shown in FIG. 1.

FIG. 5 illustrates a flowchart with acts of a method for fabricating a semiconductor device.

### DETAILED DESCRIPTION

Exemplary embodiments are described in greater detail with reference to the figures. The invention is not limited to the specifically described embodiments but can be suitably modified and altered. Individual features and feature combinations of one embodiment can be customized with features and feature combinations of other one or more embodiments, unless this is expressly excluded.

Before the following embodiments with reference to the figures are explained in detail, it should be noted that matching elements are provided in the figures with matching or similar reference numerals. In some cases, the description of such matching or similar reference numerals will not repeated. In addition, the figures are not necessarily shown to scale, since their focus is on the illustration and explanation of basic principles.

Hereinafter, a pn junction is defined as a location in a semiconductor body, in which a dopant concentration of the n-type falls within a dopant concentration of the p-type or a dopant concentration of the p-type falls within a dopant concentration of n-type or is a difference between p- and n-dopants. Dopant concentrations can be specified more precisely, where n⁻, n, n⁺, n⁺⁺, as well as p⁻, p, p⁺, p⁺⁺, with an n⁻ type doping is less than a n-type dopant, an n-type dopant impurity is smaller than an n⁺ doping and an n⁺ doping is smaller than an n⁺⁺ type doping. The foregoing is true for p⁻, p, p⁺, p⁺⁺ dopant types. Different areas, which are designated with n or p, may be modified to include other dopant concentrations, such as those provided in the foregoing.

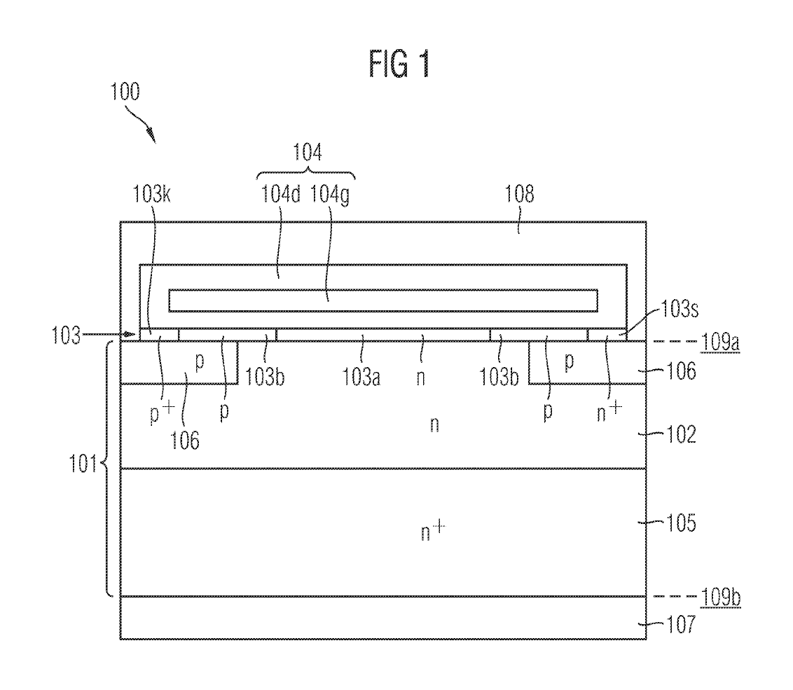

FIG. 1 shows a schematic cross-sectional view of a semiconductor device 100 that comprises a semiconductor body 101 of SiC, and a field effect transistor. The field effect transistor has a body 101 formed in the semiconductor SiC drift region 102, and a polycrystalline silicon layer 103 on a first side 109a, for example, a front side, of the semiconductor body 101. The polycrystalline silicon layer 103 has an average particle size in the range of 10 nm to 5 μm, and in particular from 50 nm to 1 μm. In addition, the polycrystalline silicon layer 103 includes a source region and a body region 103s on 103b. The field effect transistor further includes a layer 104 adjacent to the body region 103b gate structure.

As shown in FIG. 1, the semiconductor body 101 includes a SiC substrate 105 and a SiC shield region 106 within SiC drift region 102. On or over a second side 109b, for example, a rear side of the semiconductor body 101 opposite the first side 109a, is arranged a drain contact 107, such as a layer or a stack of layers of a metal and/or a metal compound. A lateral direction is approximately parallel to the first and second sides 109a, 109b, and a vertical direction perpendicular thereto. In the embodiment according to FIG. 1, the SiC substrate 105 is n+-doped, the SiC drift region 102 is doped n, the body region 103b and each of the SiC shield regions 106 are p-doped. The source region 103s is n+-doped, and the body region 103b is n-doped. Of course, the foregoing provided dopings may be reversed, so that the field effect transistor is formed as a p-channel field effect transistor. In other words, here, the embodiment of an n-channel enhancement type field effect transistor is described, but such is also analogous for a p-channel enhancement type field effect transistor.

Over the semiconductor body 101, which includes SiC, the polycrystalline silicon layer 103 disposed. As the gate structure 104 of the field effect transistor of the semiconductor device 100 is disposed over the polycrystalline silicon layer 103. In particular, a dielectric layer 104d is disposed surrounding a gate electrode 104g, for example, a polycrystalline silicon gate 104g. The dielectric layer 104d may include a plurality of parts that can be formed in different process steps and can also include different dielectric materials may. A portion of the dielectric layer 104d is formed between the gate electrode 104g and the polycrystalline silicon layer 103. The gate dielectric 104d, for example, by superficial thermal oxidation of polycrystalline silicon layer 103, may be produced by CVD deposition of a silicon oxide or a combination of these methods. However, it is also possible to produce the gate dielectric 104d from another material, for example as high-k dielectric, which has a sufficient insulation for the polycrystalline silicon gate 104

Between the gate structure 104, more specifically the dielectric layer 104d, and the drift region 102 of the semiconductor body 101 resides the polycrystalline silicon layer 103. In addition to the source region 103s and the body region 103b, the semiconductor device 100 also includes a p+-doped body contact 103k and an n-doped conduction region 103a The reduction region 103a enables electrical conduction, such as low-dissipation of electrons from one channel into the SiC drift region 102.

The SiC semiconductor body 101 is, for example monocrystalline formed while, however, the silicon layer 103 and optionally the gate 104g are comprised of polycrystalline silicon. The polycrystalline silicon layer 103 may create less strain on the the semiconductor body 101 including SiC as a monocrystalline silicon layer.

In the polycrystalline silicon layer 103, in particular on the body region 103b, an inversion channel is provided. With the described mean particle size in the range of 10 nm to 5 μm, and in particular from 50 nm to 1 μm, an electron mobility in the semiconductor material of more than 50 cm²/Vs or even more than 250 cm²/Vs is achieved. Typical mobilities are approximately in the range of 50 to 700 cm²/Vs or in the range 250 to 700 cm²/Vs. Unlike amorphous silicon structures, the improved electron mobility of the polysilicon takes place due to the larger particle size and the associated lower number of phase boundaries. A corresponding increase in the electron mobility is made possible by a further enlargement of the particles, which is achievable, for example by the deposition of amorphous silicon and a subsequent exposure to laser light. In this example, the amorphous layer is melted. After the laser irradiation, a polysilicon structure with a desired particle size. Such polycrystalline silicon is also referred to as low-temperature-poly-silicon (LTPS). The possible electron mobilities of LTPS lie approximately in the range of 100 to 700 cm²/Vs.

In addition, the use of so-called Continuous Grain Silicon (CGS) as a polycrystalline silicon layer is possible, which can offer an even higher electron mobility. CGS can provide electron mobilities of 600 cm²/Vs, and more can be achieved.

The polycrystalline silicon layer 103, for example, may be formed only in the region of the inversion channel, and not provided in a peripheral termination region of the field effect transistor of the semiconductor device 100. The inversion channel is located in the so-called cell array, which is the central component of a corresponding functional device and, in this respect of the corresponding edge-sealing areas, which serve as the lateral removal of an electric field in a blocking operation. The polycrystalline silicon layer 103 is adjacent to a source terminal portion 108, such as a source of metal.

The typical MOSFET blocking capability of the channel region is generally a few volts or some 10 volts. In the illustrated embodiments, the blocking capability is approximately the same as that found in conventional MOSFETs, despite the improved charge carrier mobility compared to a pure SiC semiconductor device. This is achieved by at least the use of the SiC semiconductor body 101 and the p-doped SiC shield region 106. The SiC shield region 106 is, for example, the realization of at a Merged Schottky diode or pure SiC MOSFETs.

The polycrystalline silicon layer 103 of the semiconductor device has a thickness d of, for example in the range of 10 nm to 600 nm or 30 nm to 250 nm. The n-doped conduction region 103a may be an individually formed layer or a layer formed continuously with the body region 103b.

Both shielding designated p-doped regions 106 in FIG. 1 can be designed as a continuous shielding region 106 or may be formed as separate shielding regions. The shielding region 106 in this case has a conductivity type which is opposite the conductivity type of the semiconductor body 101. A distance between a bottom surface of the regions 106 to the underside of the polycrystalline silicon layer 103 may be about 5% to 20% or even 10% to 20% of the thickness of the electrically active drift zone 102.

The shielding region 106 may be at its top in electrical contact to an electrical contact through an opening in the polycrystalline silicon layer 103. For example, the shielding region 106 may be in electrical contact with the source region 103s and/or the body contact 103k.

It is also possible that the shielding region 106 is electrically contacted at a top thereof to an electrical contact produced by a doped region, such as the body contact 103k, and wherein the body contact 103k also makes electrical contact with the body region 103b.

The dielectric layer 104d, which surrounds the polycrystalline silicon gate 104g is disposed over the channel region or the doped conduction region 103a of the polycrystalline silicon layer 103, and the part of the dielectric layer 104d, which forms the gate dielectric may, in accordance with different embodiments, for example be formed from a silicon oxide or a high-k dielectric.

The doped conduction region 103a, according to the embodiment of FIG. 1, is positioned between the body region 103b and the source region 103s, and the body region 103b and the source region 103s have corresponding opposite conductivity types. The body region is sometimes 103b formed between and adjacent to the source region 103s and doped conduction region 103a. As already mentioned, the individual areas, regions or layers may also be formed to have different conductivity types.

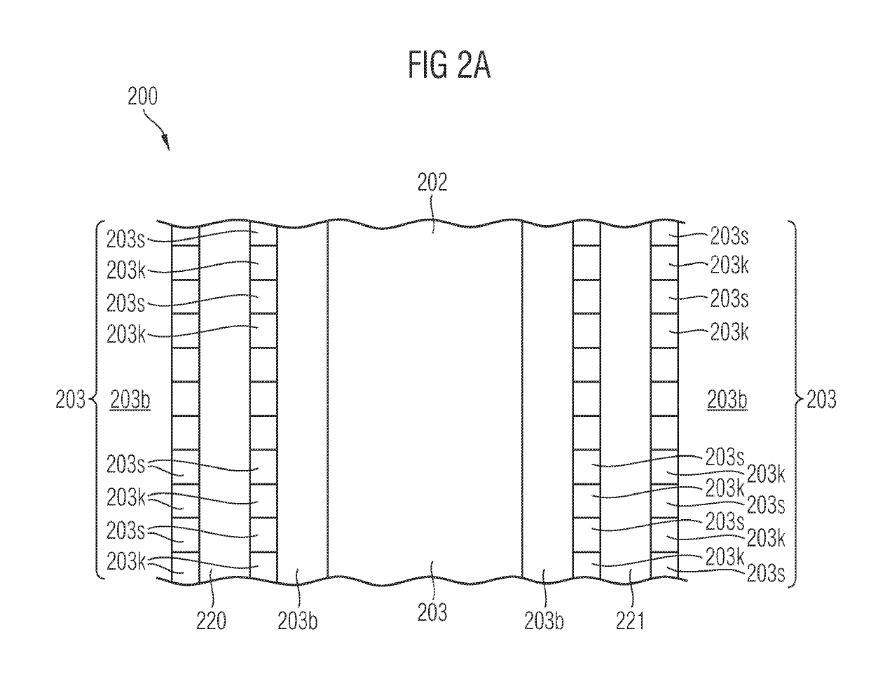

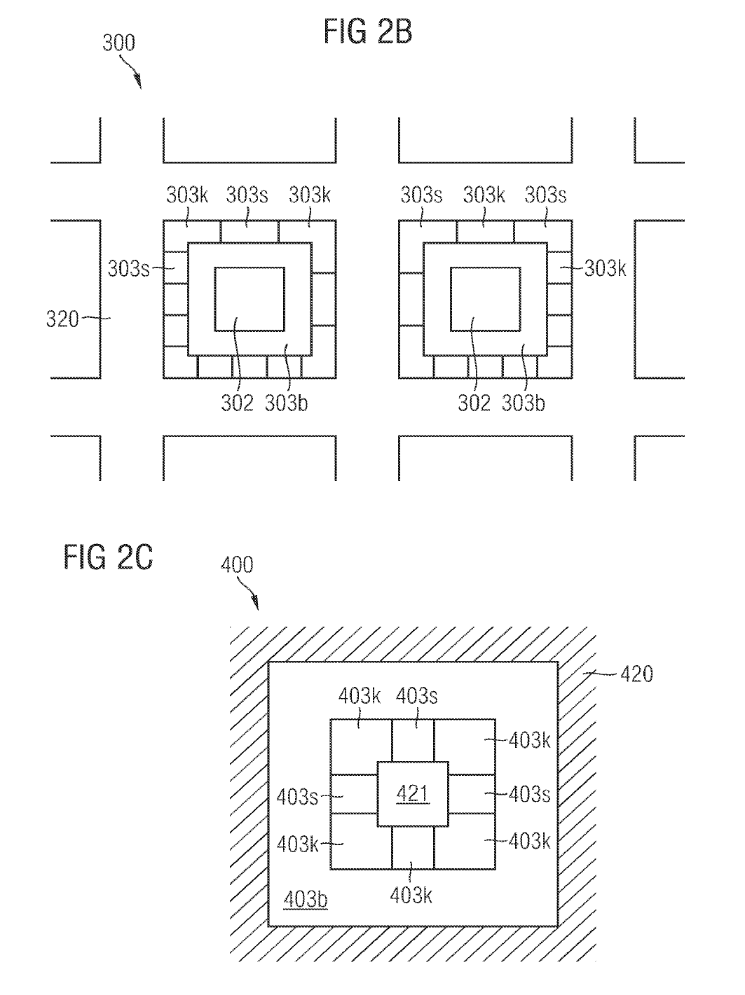

FIG. 2A illustrates a schematic plan view of an embodiment of a semiconductor device 200 having a semiconductor body made of SiC, which contains a field effect transistor. The field effect transistor has, like in the embodiment of FIG. 1, a SiC drift region 202 and a polycrystalline silicon layer 203, wherein the polycrystalline silicon layer 203 has an average particle size in the range of 10 nm to 5 μm and a plurality of source regions 203s and body areas 203b. In this example, the source region 203s are n+-doped and the body regions 203b are p-doped, with both regions formed of polycrystalline silicon in the polycrystalline silicon layer 203.

In polycrystalline silicon layer 203 also has a plurality is formed of p+-doped body contacts 203k of polycrystalline silicon, which are arranged alternately with the source regions 203s and of the opposite type of charge carrier compared to the source regions 203s. The direction runs, alternating the source regions 203s and the body contacts 203k, approximately perpendicular to the plane of the arrangement shown in FIG. 1. As is seen on the left side of the FIG. 2A, a source region 203s may be arranged adjacent to another region 203s, with a contact trench 220 disposed there between. Similarly, body contacts 203k are arranged in such a manner. As is seen on the right side of the FIG. 2A, a source region 203s may be arranged adjacent to a body contact 203k, with a contact trench 221 disposed there between. Or, body contacts 203k may be arranged adjacent to source regions 203s, with contact trenches 221 disposed there between. A polycrystalline silicon layer may be also be disposed between the body areas (not shown in FIG. 2A, see FIG. 1). FIG. 2A illustrates a strip-shaped cell design.

Another schematic plan view of an embodiment of a semiconductor device 300 is shown in FIG. 2B. The figure shows two ranges of cells, which are surrounded by a continuous contact trench 320 in a lattice shape. At the cell on the left side of FIG. 2B, the center is a drift region 302 of n-type, which is surrounded by a p-doped body region 303b. The body region 303b is in turn surrounded by source regions 303s and body contacts 303k, which are arranged alternately and form a boundary of the body region 303b. In this embodiment, each source region 303s is of the n+-type and each body contact 303k is of the p+-type.

The arrangement of the source regions 303s and the body contacts 303k according to the left-hand side of FIG. 2B is merely exemplary, and thus on the right hand side of the FIG. 2B is a deviating arrangement of the corresponding source regions 303s of body contacts 303k is shown surrounding a body region 303b, which surrounds a drift region 302. Furthermore, both cells depicted in FIG. 2B may have source regions 303s and the body contacts 303k may be arranged in a different manner. In other words, different numbers of source regions 303s and body contacts 303k may be provided to surround the respective body contacts 303b.

FIG. 2C illustrates a semiconductor device 400 in schematic plan view. A body region is 403b surrounded by a contact region 420. The body region 403b is surrounded by a plurality of successively arranged source regions 403s and body contacts 403k with mutually opposite doping. A contact region 421 is disposed in the middle of the foregoing regions.

The arrangements according to FIGS. 2A, 2B and 2C are exemplary and besides the strip-shaped or rectangular cell geometries still further cell geometries are possible, for example, hexagonal, square, or round cells forms. This is true for the respective forms of the drift region, body regions, and the source regions and body contacts.

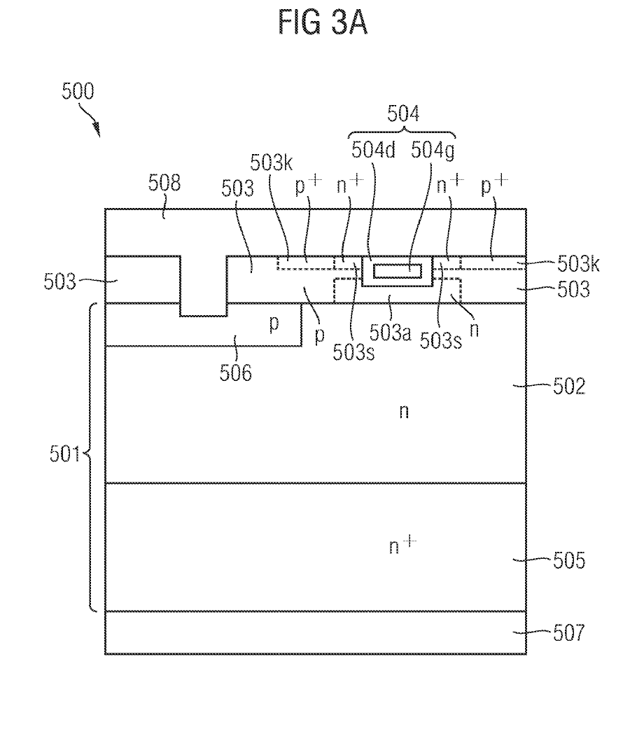

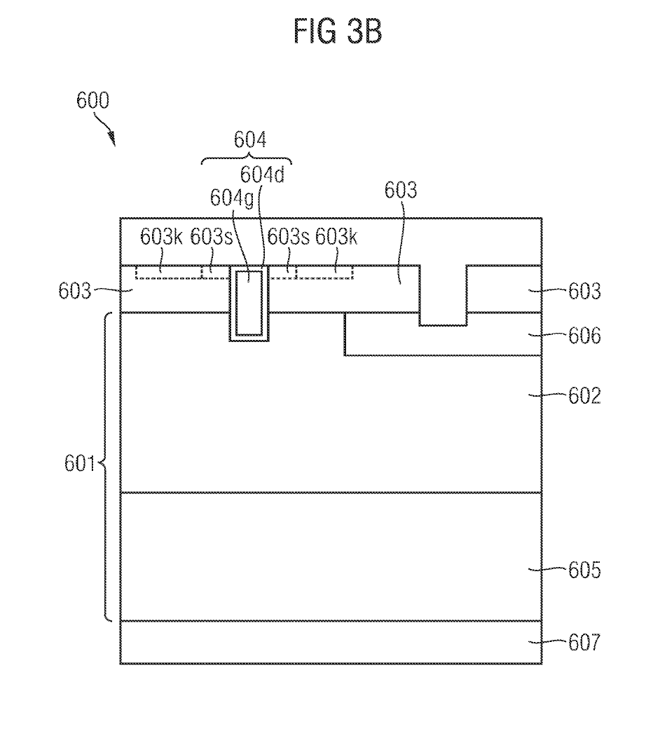

FIG. 3A illustrates a further embodiment of a semiconductor device 500 having a semiconductor body 501 of SiC and a field effect transistor, wherein the field effect transistor has a semiconductor body 501 formed of n-doped drift region 502 and a p-doped polycrystalline silicon layer 503, which includes a body region 503b having an average particle size in the range of 10 nm to 50 μm, an n+-doped source region 503s, and a p+-doped body contact 503k as well as an n-type conducting region 503a. Furthermore, the body region 503b of the field effect transistor is adjacent to and formed in a trench gate structure 504. The source region 503s, region 503a and the body contact 503k are illustrated within the polycrystalline silicon layer 503 by dashed lines, because they are formed within the layer 503 by doping. The thickness of the polycrystalline silicon layer 503 is, for example, in a range from 0.5 μm to 3 μm, or even 1 μm to 2 μm.

As seen in FIG. 3A, the field effect transistor is formed as a “grave” transistor (trench-transistor). As illustrated, the polycrystalline silicon layer 503 includes the doped conduction region 503a, a gate structure 504 having a gate electrode 504g, e.g. polycrystalline gate electrode, and a surrounding dielectric layer 504d. Between the n+-doped source region 503s and the doped conduction region 503a extends a channel region in the region adjacent to the trench portion of the body region 503b. As in FIG. 1, a shielding region 506 is formed of p-doped SiC in the SiC semiconductor body 501 in order to ensure the blocking capability of the field effect transistor.

An alternative embodiment of a semiconductor device 600 having a form of a grave transistor field-effect transistor is shown in FIG. 3B. This embodiment essentially corresponds to the embodiment illustrated in FIG. 3A. However, the field effect transistor includes a trench 604 formed from one surface of the polycrystalline silicon layer 603 by the polycrystalline silicon layer 603 and into the semiconductor body 601 of SiC. In this trench gate structure 604 is in turn formed with a dielectric layer 604d and a gate electrode 604g. Opposite the FIG. 3A, therefore, the trench 604 according to the variant of FIG. 3B is configured such that it completely penetrates the polycrystalline silicon layer 603. A channel region thus ends at the transition of the polycrystalline silicon layer 603 to the semiconductor body 601 of SiC.

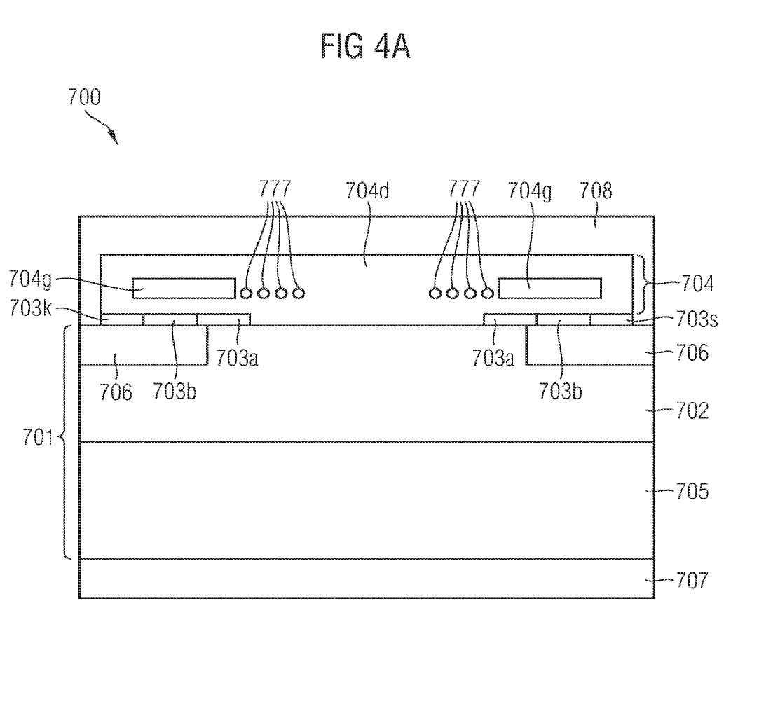

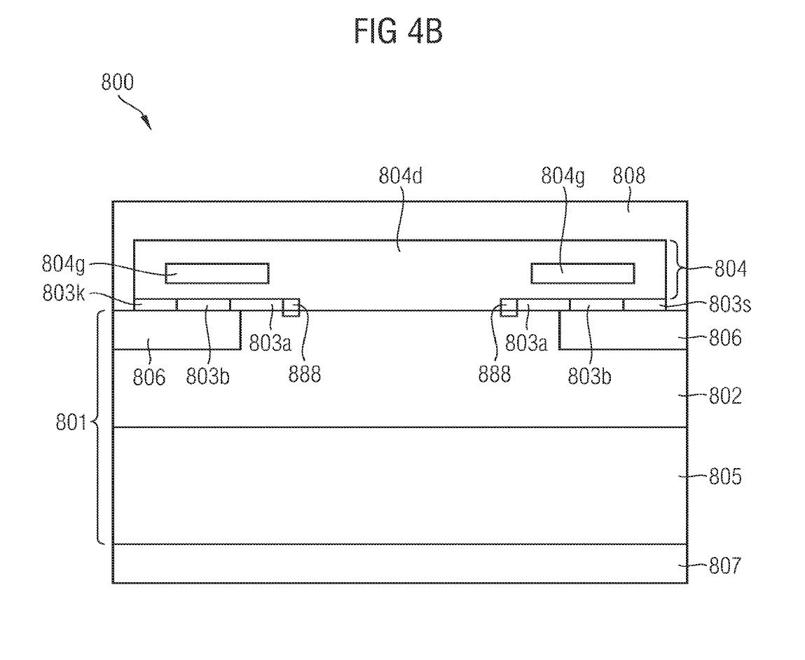

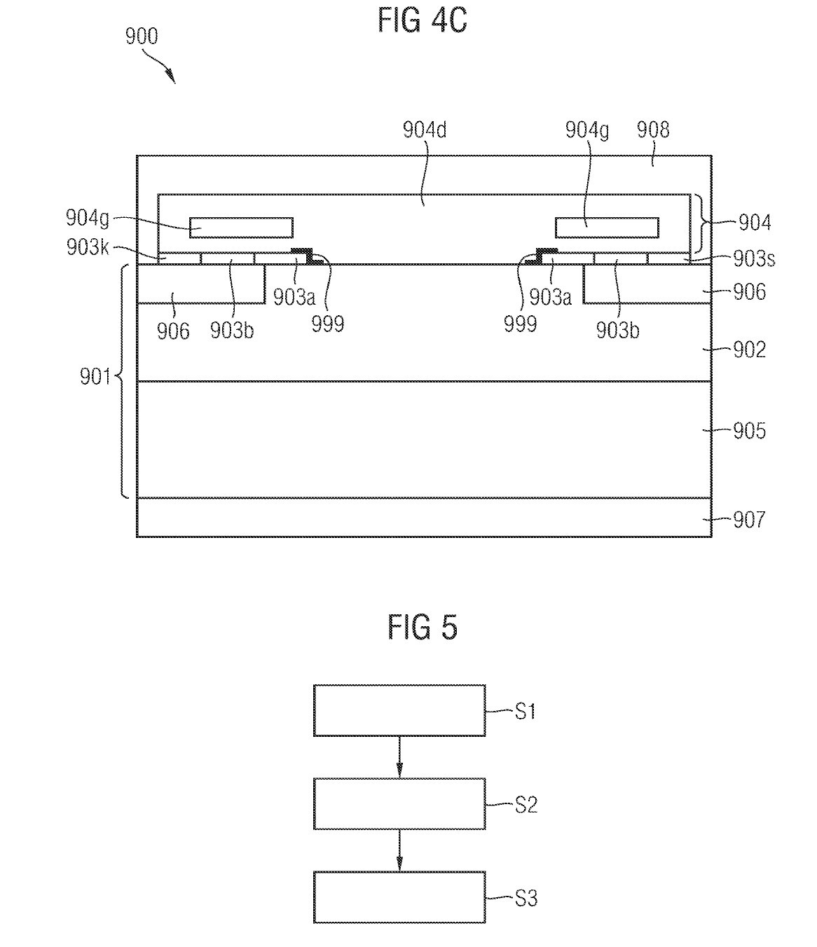

FIGS. 4A to 4C illustrate schematic sectional views of further modifications 700, 800, 900 of the semiconductor devices, in particular the semiconductor device illustrated in FIG. 1. Therefore, features 701, 702, 703, 703s, 703b, 703k, 704, 704g, 704d, 705, 706, 707, 708 or 801, 802, 803, 803s, 803b, 803k, 804, 804G, 804d, 805, 806, 807, 808 or 901, 902, 903, 903S, 903b, 903k, 904, 904g, 904d, 905, 906, 907, 908 are related to corresponding reference numerals of the features 101, 102, 103, 103s, 103b, 103k, 104, 104g, 104d, 105, 106, 107, 108 illustrated and described herein with reference to FIG. 1.

In FIG. 4A, the illustrated gate electrode 704g is formed in two parts, so that the region of to n+-doped source region 703s and the region of the p+-doped body contact 703k are each provided with its own gate electrode 704g. In addition, the n-doped conduction regions 703a are not contiguous. Furthermore, next to the gate electrode 704g of the dielectric layer 704d, the gate structure 704 is formed with positive charge carriers charge islands 777, which are formed approximately after patterning of the gate electrode 704g, for example by application of Cs. The positive charge carriers charge islands 777 provide an electron accumulation in the n-doped conduction regions 703a and to the semiconductor body 701 of SiC.

In FIG. 4B, as in FIG. 4A, the illustrated n-doped conduction regions 803a are not contiguous. Between each n-doped conduction regions 803a and the drift region 802 of the semiconductor body 801 is formed one degeneration area 888, which has in the way of example here associated conductivity type is an n++-type doping. The degeneration area 888 is at least partially formed in the polycrystalline silicon layer 804, and may extend into the semiconductor body 801 of SiC. The highly doped region results in a degeneration Si/SiC heterojunction, thereby improving the charge carrier flow through the heterojunction Si/SiC. The degeneration field is generated, for example, by ion implantation and/or diffusion of dopants.

In FIG. 4C the n-doped conduction regions 903a are not contiguous. Instead of degeneration areas 888 as shown in FIG. 4B, metal regions 999 are formed. These metal regions 999 can be used in the form of a metal strap, for example, and may be a deposited and patterned metallization formed to produce an electrical contact between the n-doped conduction region 903a and the drift region 902. For example, forming the metal areas, including, for example NiAl, forms an ohmic contact to the n-doped conduction region 903 of polycrystalline silicon and to the semiconductor body of SiC 901. It is also possible to feed the metal regions 999 with the p-SiC doped shielding region 906.

FIG. 5 shows schematically a sequence of process acts according to a method of manufacturing a semiconductor device according to the above description. With the method of a field effect transistor is produced, wherein the following steps are performed: forming a polycrystalline silicon layer on a semiconductor body made of SiC, wherein the polycrystalline silicon layer has an average grain size in the range of 10 nm to 5 μm, and in particular from 50 nm to 1 μm (Act S1), forming a body region and a source region within the polycrystalline silicon layer (Act S2), and forming the body region adjacent a gate structure (Act S3).

The semiconductor body is preferably made of SiC, and in particular, a single crystal SiC, wherein different portions may already be doped in-situ, that is, during the respective crystal growth, and/or for instance by ion implantation and/or diffusion. For example, the body region can be doped in-situ and the source region, body contact region and conduction region doped by ion impanation. Likewise, all the regions in the polycrystalline silicon layer can be doped by ion impanation. The silicon layer, as described above, may be formed of polycrystalline having a particle size of 10 nm to 5 μm, and in particular from 50 nm to 1 μm. This first amorphous silicon can be deposited, and subsequently adapted to be irradiated with laser light, so that an appropriate particle size is established. The amorphous layer can for example be fused to the SiC semiconductor body by means of laser irradiation and recrystallized or transferred into a separate process first in the particle structure, and are then applied to the SiC semiconductor body. Polycrystalline silicon constructed in this way is known as low-temperature poly-silicon (LTPS). The possible electron mobilities of LTPS lie approximately in the range 100-700 cm²/Vs.

In a further development of the method of FIG. 5, the polycrystalline silicon layer is removed in a peripheral termination region of the field effect transistor.

Within the SiC semiconductor body for example, before formation of the polycrystalline silicon layer, doped shield regions be formed by diffusion and/or ion impanation to ensure a blocking capability of the device to be manufactured. The shield regions may be doped opposite to the semiconductor body.

For the purposes of this disclosure and the claims that follow, the terms “coupled” and “connected” have been used to describe how various elements interface. Such described interfacing of various elements may be either direct or indirect. Although the subject matter has been described in language specific to structural features and/or methodological acts, it is to be understood that the subject matter defined in the appended claims is not necessarily limited to the specific features or acts described. Rather, the specific features and acts are disclosed as preferred forms of implementing the claims. The specific features and acts described in this disclosure and variations of these specific features and acts may be implemented separately or may be combined.

1-19. (canceled).

20. A semiconductor device, comprising:
a semiconductor body made of SiC; and
a field effect transistor, comprising:
a drift region in the semiconductor body;
a polycrystalline silicon layer directly on the semiconductor body, the polycrystalline silicon layer having an average particle size in a range of 10 nm to 50 μm, the polycrystalline silicon layer comprising a source region and a body region in contact with the source region; and
a gate trench adjacent the body region and extending from a surface of the polycrystalline silicon layer into the polycrystalline silicon layer, wherein a gate structure is formed within the gate trench.

21. The semiconductor device of claim 20, wherein the body region comprises a channel region adjacent a vertical surface of the gate trench.

22. The semiconductor device of claim 21, wherein the channel region extends to a surface of the semiconductor body.

23. The semiconductor device of claim 20, wherein the gate trench extends into the semiconductor body.

24. The semiconductor device of claim 20, wherein the polycrystalline silicon layer further comprises a conduction region disposed between the body region and the drift region, wherein the drift region is in direct contact with the conduction region.

25. The semiconductor device of claim 20, wherein a carrier mobility μ in the body region is approximately 50 cm²/(Vs)-700 cm²/(Vs).

26. The semiconductor device of claim 20, wherein a thickness of the polycrystalline silicon layer is in the range of 10 nm to 600 nm.

27. The semiconductor device of claim 20, wherein a thickness of the polycrystalline silicon layer ranges from 0.5 μm to 3 μm.

28. The semiconductor device of claim 20, further comprising a shielding region formed in the semiconductor body, the shielding region having a conductivity type opposite to a conductivity type of the drift region.

29. The semiconductor device of claim 28, wherein a distance between a bottom of the shielding region and a bottom of the polycrystalline silicon layer is between 5% and 20% of a thickness of the drift region.

30. The semiconductor device of claim 28, wherein the shielding region contacts the polycrystalline silicon layer.

31. The semiconductor device of claim 28, wherein the shielding region is electrically coupled to an electrical contact provided by a doped body contact region, the doped body contact region electrically coupled to the body region.

32. The semiconductor device of claim 24, wherein the conduction region has an opposite conductivity type as one of the source region and the body region.

33. The semiconductor device of claim 32, further comprising a metallic short circuit coupled between the conduction region and the semiconductor body.

34. The semiconductor device of claim 32, further comprising a charge accumulation region dielectrically separated from the semiconductor body, the charge accumulation region configured to provide a carrier accumulation.

35. The semiconductor device of claim 32, further comprising a degeneration region formed between the conduction region and the semiconductor body.

36. The semiconductor device of claim 20, wherein the field effect transistor is an n-channel field effect transistor with a vertical current flow between the source region and a drain region, the source region associated with a first surface of the semiconductor body and the drain region associated with a second surface, opposite of the first surface, of the semiconductor body.

37. A semiconductor device, comprising:
a semiconductor body made of SiC; and
a field effect transistor, comprising:
a drift region in the semiconductor body;
a polycrystalline silicon layer directly on the semiconductor body, the polycrystalline silicon layer having an average particle size in a range of 10 nm to 50 μm, the polycrystalline silicon layer comprising a source region, a channel region, and a conduction region, the channel region disposed between the source region and the conduction region, wherein the drift region is in direct contact with the conduction region; and
a gate trench adjacent the channel region and extending from a surface of the polycrystalline silicon layer into the polycrystalline silicon layer, wherein a gate structure is formed within the gate trench, wherein the channel region is adjacent a vertical surface of the gate trench.

38. The semiconductor device of claim 37, wherein the gate trench extends into the semiconductor body.

39. A method for producing a semiconductor device, comprising:
forming a polycrystalline silicon layer on a semiconductor body made of SiC, the polycrystalline silicon layer having an average particle size in the range of 10 nm to 50 μm;
forming a body region and a source region of a field effect transistor within the polycrystalline silicon layer, the body region being in contact with the source region;
forming a gate trench adjacent the body region and extending from a surface of the polycrystalline silicon layer into the polycrystalline silicon layer; and
forming a gate structure within the gate trench.
